(19) United States
(12) Patent Application Publication
(10) Pub. No.: US 2016/0348233 A1
(43) Pub. Date: Dec. 1, 2016

(54) GROUNDING OF CONDUCTIVE MASK FOR DEPOSITION PROCESSES

(71) Applicant: Applied Materials, Inc., Santa Clara, CA (US)

(72) Inventors: JIN MAN HA, Cheonan City Chungnam (KR); JAE JUNG KIM, Cheonan-Si Chungcheongnam-do (KR); YONG KYUN JEONG, Ssangyong dong (KR); CHUNG HEE PARK, Seoul (KR); SOO YOUNG CHOI, Fremont, CA (US)

(21) Appl. No.: 14/813,061

(22) Filed: Jul. 29, 2015

Related U.S. Application Data
(60) Provisional application No. 62/168,341, filed on May 29, 2015.

(51) Int. Cl. C23C 16/04; C23C 16/458

(52) U.S. Cl. CPC C23C 16/042; C23C 16/4585

(57) ABSTRACT

Embodiments of the disclosure include methods and apparatus for electrically grounding a shadow mask for use in a deposition chamber. In one embodiment, a substrate support is provided and includes a substrate receiving surface, and a plurality of compressible grounding devices disposed about a periphery of the substrate receiving surface. Each of the plurality of grounding devices comprises a base member fixed to the substrate support, and a biasing assembly movably disposed in the base member.

### CROSS-REFERENCE TO RELATED APPLICATION

This application claims benefit of U.S. Provisional Patent Application Ser. No. 62/168,341 (Attorney docket No.: 022891/USL) filed May 29, 2015, which application is hereby incorporated by reference herein.

### BACKGROUND

1. Field

Embodiments of the disclosure relate to methods and apparatus for grounding a conductive shadow mask for use in a deposition process, such as a plasma enhanced chemical vapor deposition (PECVD) process used in the manufacture of electronic devices. In particular, embodiments of the disclosure relate to electrical grounding of a metallic shadow mask utilized in an encapsulation process in the manufacture of organic light emitting diode (OLED) display devices.

2. Description of the Related Art

Organic light emitting diodes (OLEDs) are used in the manufacture of television screens, computer monitors, mobile phones, other hand-held devices, etc. for displaying information. A typical OLED may include layers of organic material situated between two electrodes that are all deposited on a substrate in a manner to form a matrix display panel having individually energizable pixels. The OLED is generally placed between two glass panels, and the edges of the glass panels are sealed to encapsulate the OLED therein.

There are many challenges encountered in the manufacture of such display devices. In some fabrication steps, the OLED material is encapsulated in one or more layers to prevent moisture from damaging the OLED material. During these processes, one or more masks are utilized to shield portions of the substrate that do not include the OLED material. The masks are carefully positioned relative to the substrate in order to control deposition. The masks utilized in these processes are typically metals or metal alloys having a relatively low coefficient of thermal expansion. However, during plasma processing, the mask is typically electrically floating and electrons tend to accumulate across surfaces of the mask. The accumulation of electrons may cause an electrical discharge or arcing, which may damage the mask. Arcing may also cause the mask to deform slightly which may cause the mask to be misaligned relative to the substrate. Misalignment of the mask may negatively affect deposition and may prevent proper deposition on one or more devices on the substrate, rendering these devices unusable. Arcing may also generate undesirable particles, which decreases device yield.

Therefore, there is a need for methods and apparatus for grounding masks during the formation of OLED display devices.

### SUMMARY

Embodiments of the disclosure include methods and apparatus for electrically grounding a shadow mask for use in a deposition chamber. In one embodiment, a substrate support is provided and includes a substrate receiving surface, and a plurality of compressible grounding devices disposed about a periphery of the substrate receiving surface. Each of the plurality of grounding devices comprises a base member fixed to the substrate support, and a biasing assembly movably disposed in the base member.

In another embodiment, a substrate support is provided and includes a substrate receiving surface, and a plurality of compressible grounding devices disposed on a recessed surface along a periphery of the substrate receiving surface. Each of the plurality of grounding devices comprises a base member fixed to the substrate support, and a biasing assembly movably disposed in the base member.

In another embodiment, a substrate support is provided and includes a substrate receiving surface, and a plurality of compressible grounding devices disposed about a periphery of the substrate receiving surface. Each of the plurality of grounding devices comprises a base member fixed to the substrate support about an opening in a surface of the substrate support, a pin movably disposed in the base member, a top cover disposed about the pin, a plurality of biasing members disposed between the top cover and the base member; and one or more conductive wires coupled between the pin and the substrate support.

### BRIEF DESCRIPTION OF THE DRAWINGS

So that the manner in which the above recited features can be understood in detail, a more particular description of embodiments of the disclosure, briefly summarized above, may be had by reference to the embodiments, some of which are illustrated in the appended drawings. It is to be noted, however, that the appended drawings illustrate only typical embodiments and are therefore not to be considered limiting of its scope, for the disclosure may admit to other equally effective embodiments.

FIG. 1 is a schematic cross-sectional view of a plasma enhanced chemical vapor deposition (PECVD) chamber according to one embodiment.

FIG. 2 is an exploded isometric view of interior chamber components used in the chamber body of the PECVD chamber of FIG. 1.

FIG. 3A is an enlarged cross-sectional view side cross-sectional view of a portion of the substrate support of FIG. 1.

FIG. 3B is an enlarged cross-sectional view of a portion of the frame of the mask of FIG. 1 or FIG. 2, as well as a portion of the substrate support and the shadow frame of FIG. 1 or 2.

FIG. 4 is an isometric top view of one embodiment of a grounding device that may be used in the chamber of FIG. 1.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the disclosure include methods and apparatus for electrically grounding a shadow mask for use in a deposition chamber. The mask may be utilized in a plasma-enhanced chemical vapor deposition (PECVD) process chamber that is operable to align the mask with respect to a substrate, position the mask on the substrate, and deposit an encapsulation layer on an OLED material formed on the substrate. The embodiments described herein may be used with other types of process chambers and are not limited to use with PECVD process chambers. The embodiments described herein may be used with other types of deposition processes and are not limited to use for encapsulating OLED's formed on substrates. The embodiments described herein may be used with various types, shapes, and sizes of masks and substrates. Furthermore, a suitable chamber that may benefit from the masks disclosed herein is available from AKT America, Inc., Santa Clara, Calif., which is a subsidiary of Applied Materials, Inc., Santa Clara, Calif.

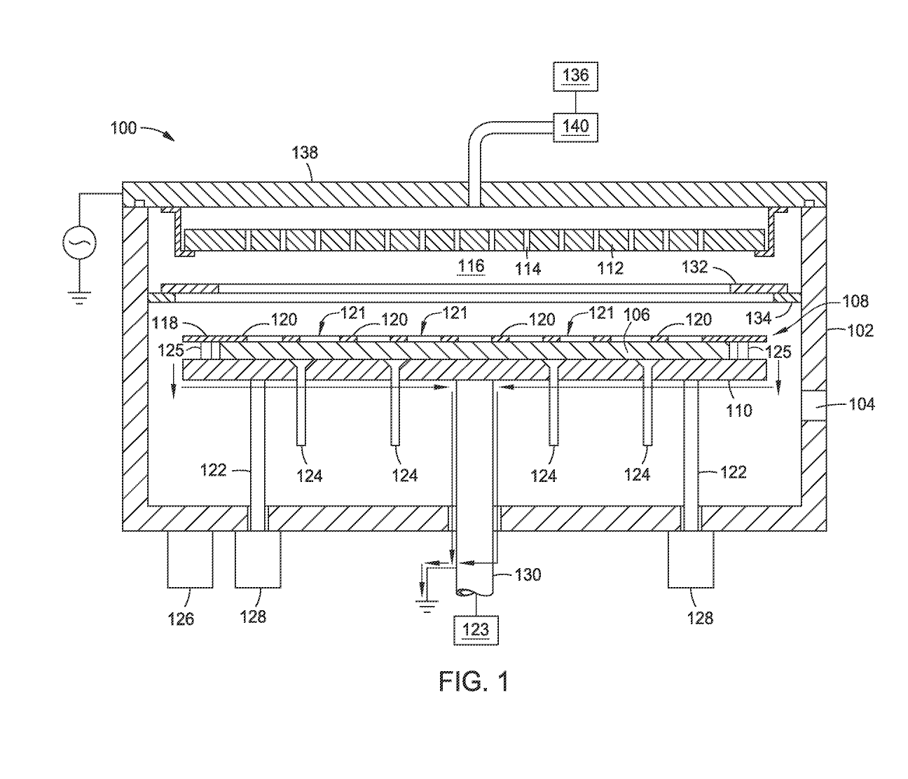

FIG. 1 is a schematic cross-sectional view of a PECVD chamber 100 according to one embodiment. The PECVD chamber 100 includes a chamber body 102 having an opening 104 through one or more walls to permit one or more substrates 106 and a mask 108 to be inserted therein. The substrate 106, during processing, is disposed on a substrate support 110 opposite a diffuser 112. The diffuser 112 has one or more openings 114 formed therethrough to permit processing gas to enter a processing space 116 between the diffuser 112 and the substrate 106.

The substrate 106 may be used to form an OLED display where OLED's are formed on the surface of the substrate 106 by sequential deposition processes in the PECVD chamber 100. The substrate 106 may be glass substrate, a polymer substrate, or other suitable material for forming electronic devices. The substrate 106 may be rigid or flexible. The substrate 106 may be used to form a single display or multiple displays. Each display includes a plurality of OLEDs coupled to an electrical contact layer formed about a perimeter of each display. During manufacture, the OLED portion of each display is encapsulated in one or more layers to protect the OLED's from the environment. The layers may comprise one or a combination of silicon nitride, aluminum oxide, and/or a polymer material. The encapsulation material may be deposited by a PECVD process in the PECVD chamber 100. The mask 108 is used to shield the electrical contact layer of the OLEDs during deposition of the encapsulation material. The mask 108 includes a frame 118 and a plurality of open areas or slots 121. Each slot 121 may be sized according the size of the OLED portion of each display. The encapsulation material is deposited on the OLED portion of each display through the slots 121. Outward of and between each slot 121 is a strip 120 that shields the electrical contact layer during the encapsulation process.

One or more grounding devices 125 may be utilized to electrically couple the mask 108 to the substrate support 110, which is coupled to ground potential. The mask 108, including the frame 118 and the strips 120, are made of a conductive material, such as a metallic alloy material. In one embodiment, the mask 108 comprises a material having a low coefficient of thermal expansion. Examples of metallic alloys include KOVAR® alloys (Ni—Co) and INVAR® alloys (Ni—Fe). The substrate support 110 and the grounding devices 125 may be made of an electrically conductive material, such as aluminum. Thus, electrons that accumulate on the substrate 106 and/or the mask 108 during PECVD processing may be transferred to ground potential through or on the mask 108, the grounding devices 125 and the substrate support 110. In one embodiment, the grounding devices 125 are compressible to provide grounding when spacing between the frame 118 and the substrate support 110 is variable and/or non-uniform.

For processing, the mask 108 is initially inserted into the PECVD chamber 100 through the opening 104 and disposed upon multiple motion alignment elements 122. The substrate support 110 is disposed on a stem 130 that is coupled to an actuator 123. The elevation of the substrate support 110 in the PECVD chamber 100 may be controlled by the actuator 123. When the substrate support 110 is lowered to a level adjacent to the opening 104, the substrate 106 may be inserted though the opening 104 and disposed upon multiple lift pins 124 that extend through the substrate support 110. The substrate support 110 then raises to meet the substrate 106 so that the substrate 106 is supported on the substrate support 110. The substrate 106 may be aligned while on the substrate support 110.

Once the substrate 106 is aligned on the substrate support 110, one or more visualization systems 126 determine whether the mask 108 is properly aligned over the substrate 106. If the mask 108 is not properly aligned, one or more actuators 128 move one or more motion alignment elements 122 to adjust the location of the mask 108 relative to the substrate support 110. The one or more visualization systems 126 may then recheck the alignment of the mask 108 to verify alignment.

Once the mask 108 is properly aligned over the substrate 106, the mask 108 is lowered onto the substrate 106, and the substrate support 110 is raised until a shadow frame 132 contacts the mask 108. The shadow frame 132, prior to resting on the mask 108, is disposed in the chamber body 102 on a ledge 134 that extends from one or more interior walls of the chamber body 102. The substrate support 110 continues to rise until the substrate 106, mask 108 and shadow frame 132 are disposed in the processing position opposite the diffuser 112. Processing gas is then delivered from one or more gas sources 136 through an opening formed in a backing plate 138 while an electrical bias is provided to the diffuser 112 to form a plasma in the processing space 116 between the diffuser 112 and the substrate 106. Alternatively, a remote plasma source 140 may energize processing gas is then delivered from one or more gas sources 136 to provide a plasma to the processing space 116. Temperatures during processing may be about 80 degrees Celsius (° C.) to about 100° C., or greater.

Good contact between the mask 108 and the substrate 106 is desired in order to control deposition of the encapsulating layers and/or to prevent a “shadow” effect at the edges of the slots 121. For example, the strips 120 should lie directly on the substrate 106 to contain encapsulation material during deposition. When there is insufficient contact, the encapsulation material may cover portions of the substrate 106 that are supposed to be shielded. Contact in the center area of the mask 108 is typically satisfactory due to the effect of gravity. However, edges and/or corners of the mask may not provide sufficient contact. In areas where insufficient contact exists, encapsulation material may cover the electrical contact layer of the OLED's.

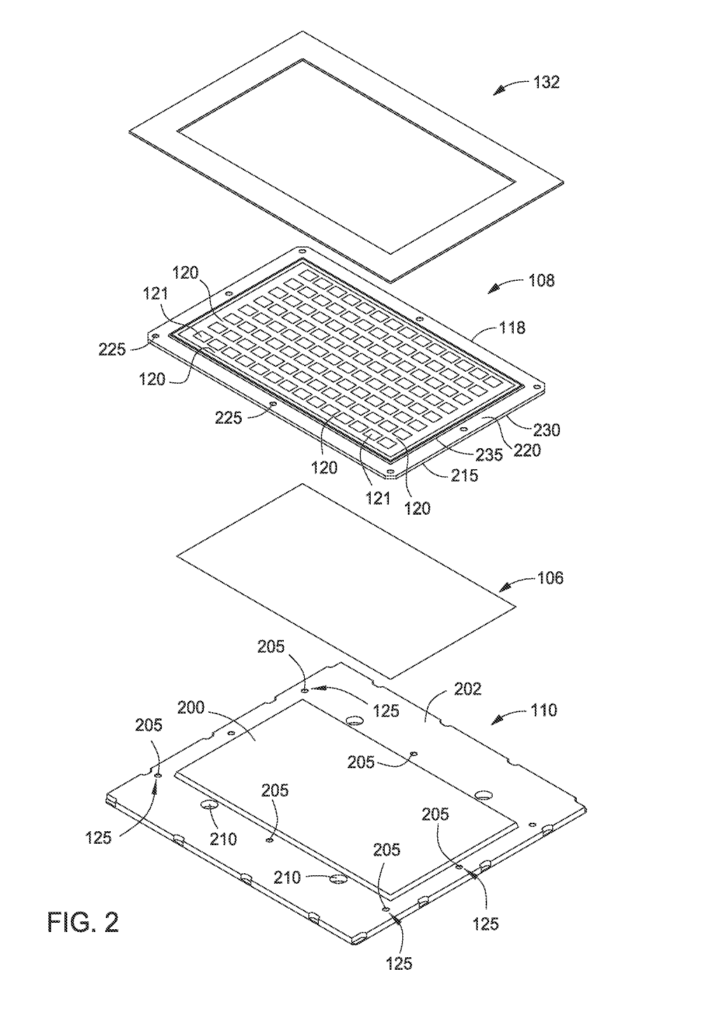

FIG. 2 is an exploded isometric view of interior chamber components used in the chamber body 102 of the PECVD chamber 100 of FIG. 1. In FIG. 2, the substrate 106 rests on a substrate receiving surface 200 of the substrate support 110 during processing. The substrate support 110 is typically fabricated from an aluminum material. A recessed surface 202 of the substrate support 110 includes a plurality of grounding devices 125. In one embodiment, each of the grounding devices 125 may be compressible buttons 205. The substrate 106 is at least partially overlaid by the mask 108 and the shadow frame 132 at least partially overlies the mask 108. The shadow frame 132 is typically fabricated from an aluminum material. The mask 108 and the shadow frame 132 may include dimensions of greater than about 0.5 meters (m) in length by 0.5 m in width. Openings 210 are shown in the substrate support 110 for access of the one or more motion alignment elements 122 to extend therethrough and contact and/or move the mask 108 relative to the substrate 106 to ensure proper alignment therebetween.

The frame 118 also includes a first side 215 on a lower surface thereof and a second side 220 opposing the first side 215. The second side 220 may comprise a plurality of depressions 225 that mate with projections (not shown) on a lower surface of the shadow frame 132. The depressions 225 and projections (not shown) facilitate indexing and alignment of the shadow frame 132 with the mask 108. The first side 215 is joined with the second side 220 by a first outer sidewall 230. The frame 118 also includes a raised region 235 projecting from a plane of the second side 220. The strip 120 is coupled to an upper surface of the raised region 235. The strip 120 may be a substantially planar rectangular member that is fastened to the frame 118. The strip 120 projects inwardly from the raised region 235 in a plane that is substantially parallel with a plane of one or both of the first side 215 and the second side 220.

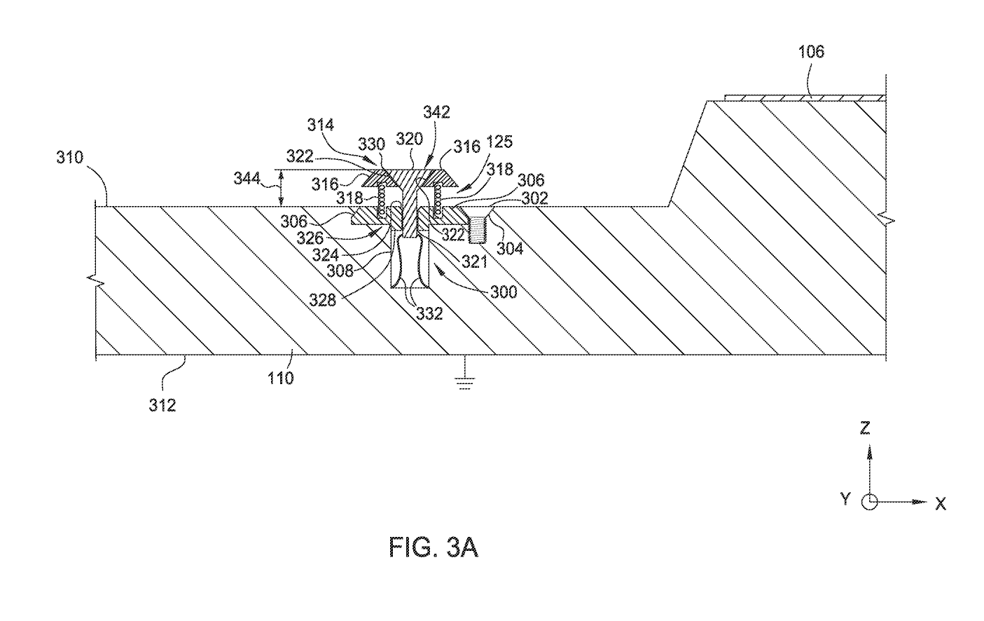

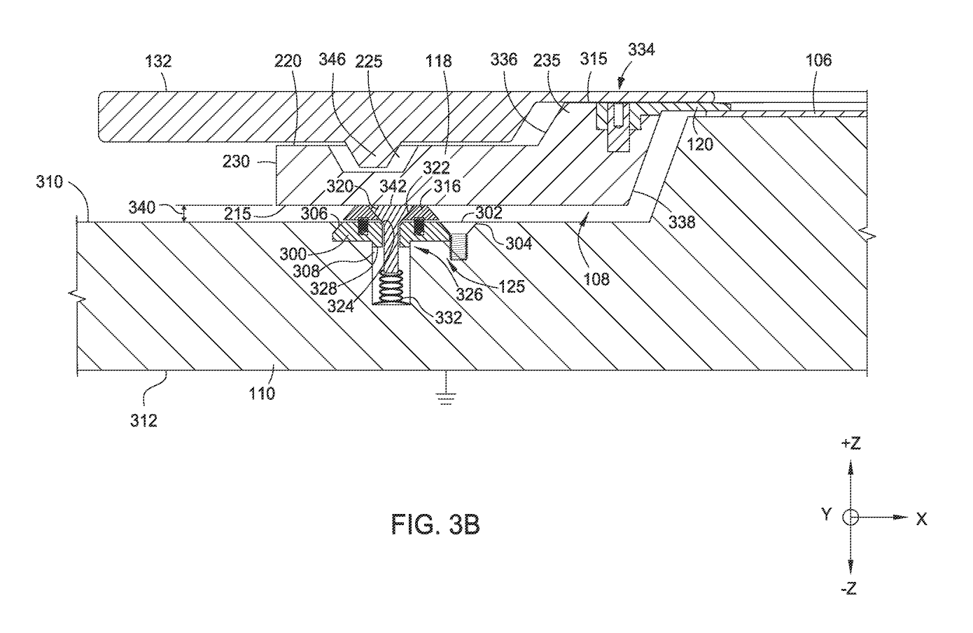

FIG. 3A is an enlarged cross-sectional view side cross-sectional view of a portion of the substrate support 110 of FIG. 1. The substrate support 110 has the substrate 106 thereon in a processing position. One embodiment of a grounding device 125 is shown in FIG. 3A. The grounding device 125 may comprise one or more of the grounding devices 125 shown in FIGS. 1 and 2. FIG. 3B is an enlarged cross-sectional view of a portion of the frame 118 of the mask 108 of FIG. 3A, as well as a portion of the substrate support 110 and the shadow frame 132. The grounding device 125 shown in FIG. 3A is in an extended or uncompressed position. The grounding device 125 shown in FIG. 3B is in a non-extended or compressed position. The position shown in FIG. 3A may be a processing position and may be utilized to provide a path for electrons that accumulate on the substrate 106 and/or the mask 108 during PECVD processing. The electrons may be transferred to ground potential through or on the mask 108, the grounding device 125 and the substrate support 110.

As shown in FIGS. 3A and 3B, the grounding device 125 includes a base member 300 that is fixed to the substrate support 110. In one embodiment, the base member 300 is fixed to the substrate support 110 by a fastener 302. The fastener 302 may be a bolt or a screw. In one embodiment, the fastener 302 includes a sloped head 304 that may interface with a sloped surface 306 of the base member 300. The base member 300 is at least partially disposed in an opening 308 that is formed in a first surface 310 of the substrate support 110. The first surface 310 is opposite to a second surface 312 of the substrate support 110.

The grounding device 125 also includes a biasing assembly 314 that is movably coupled to the base member 300. The biasing assembly 314 may include a top cover 316 that is mechanically biased against the base member 300 by one or more biasing members 318. The biasing members 318 may be compression springs or coil springs in one embodiment. The biasing assembly 314 may also include a pin 320. The pin 320 is sized to move within an internal opening 321 of the base member 300 along the Z direction. The pin 320 may include a sloped surface 322 that is substantially the same as a sloped surface 324 of the base member 300. The pin 320 may be stabilized in the Y and the X direction by a throat portion 326 of the base member 300. The throat portion 326 may include a protruding shoulder 328 extending from a surface of the base member 300 into the opening 308. The sloped surface 322 may also be substantially the same as an internal surface 330 of the top cover 316. In some embodiments, the pin 320 and the top cover 316 move together relative to the base member 300 in the Z direction. In other embodiments, the pin 320 and the top cover 316 may be separated such that one could move relative to the other. The pin 320 may be made of an electrically conductive material. The top cover 316 may also be made of an electrically conductive material. In some embodiments, the base member 300 is made of an electrically conductive material. The electrically conductive material may comprise an aluminum material.

The grounding device 125 includes one or more conductive wires 332 coupled between the pin 320 and the substrate support 110. The conductive wires 332 are utilized to provide a path for electrical current from the pin 320 and/or the top cover 316 to the substrate support 110, and to ground potential. The conductive wires 332 may comprise an electrically conductive material that is flexible. Examples of the conductive material include copper, aluminum, among other conductive metals. The conductive wires 332 may be in solid form or braided.

The conductive wires 332 may include a length that provides movement of the pin 320 in at least the Z direction without binding or hindrance. In one embodiment, the length of the conductive wires 332 is utilized as a stop for the pin 320. For example, when the pin 320 is extended as shown in FIG. 3A, the length of the conductive wires 332 are such that the pin 320 is restrained in the opening 308 along the Z direction.

FIG. 3B is an enlarged cross-sectional view of a portion of the frame 118 of the mask 108 of FIG. 1 or FIG. 2, as well as a portion of the substrate support 110 and the shadow frame 132. During processing, a perimeter of the substrate 106 is shielded by the strip 120. A portion of the frame 118 and the strip 120 may be shielded by the shadow frame 132. During processing, the first side 215 of the frame 118 compresses the grounding device 125 as shown in FIG. 3B.

The compressibility of the grounding device 125 serves to provide electrical contact between the frame 118 and the substrate support 110 over various distances. For example, a gap 340 between the first surface 310 of the substrate support 110 and the first side 215 of the frame 118 may be designed to be about 3 millimeters (mm). As shown in FIG. 3B, the top cover 316 and the pin 320 are compressed and are near a travel limit in the Z direction according to the gap 340 dimension. However, planarity of one or both of the first surface 310 of the substrate support 110 and the first side 215 of the frame 118 may not be within that tolerance across the whole thereof. The pin 320 and/or the top cover 316 of the grounding device 125 may be adapted to move about 1.3 mm in the Z direction. In the example shown in FIG. 3B, a contact surface 342 of biasing assembly 314 (i.e., the top cover 316 and/or the pin 320) may be about 3.2 mm to about 3.5 mm from the first surface 310 of the substrate support 110. This allows movement of the biasing assembly 314 in the −Z direction if the gap 340 is slightly out of tolerance. In the example shown in FIG. 3A, the biasing assembly 314 may be fully extended such that the contact surface 342 includes a height 344 that is near 1.3 mm. Thus, the grounding device 125 has an adjustable height that may be within about 1.3 mm from the first surface 310 of the substrate support 110.

Also shown in FIG. 3B is a fastener assembly 334 that couples the frame 118 to the strip 120 along the raised region 235. The fastener assembly 334 may be utilized to index and fix the strip 120 to the frame 118. The raised region 235 extends from a plane of the second side 220 and is joined to the second side 220 by a second outer sidewall 336. An interior sidewall 338 joins the first side 215 with a support surface 315 of the raised region 235. As described in FIG. 2, the second side 220 of the frame 118 comprises a plurality of depressions 225 that mate with projections 346 (only one is shown) on a lower surface of the shadow frame 132. The depression 225 and projection 346 facilitate indexing and alignment of the shadow frame 132 with the mask 108.

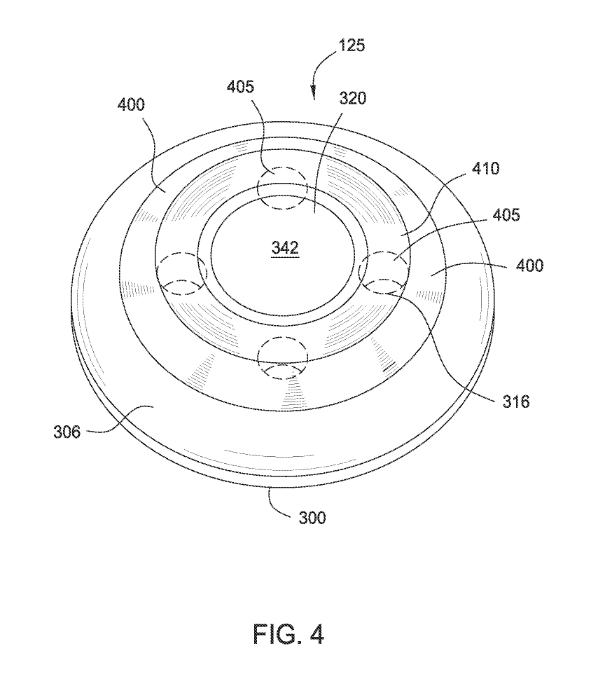

FIG. 4 is an isometric top view of one embodiment of a grounding device 125 that may be used in the PECVD chamber 100 of FIG. 1. The grounding device 125 includes base member 300 having the sloped surface 306. The top cover 316 is positioned concentric to the base member 300. In some embodiments, the top cover 316 includes a sloped surface 400. The angle of the sloped surface 400 of the top cover 316 may be substantially the same as the angle of the sloped surface 306 of the base member 300. Also shown is a plurality of recesses 405 (shown in dashed lines) below an upper surface 410 of the top cover 316. Each of the recesses 405 may house a biasing member 318 (shown in FIGS. 3A and 3B).

Disclosed herein are methods and apparatus for electrically grounding a shadow mask for use in a deposition chamber. A substrate support 110 having a plurality of grounding devices 125 as described herein provide a longer lifetime for a mask. Testing of the grounding devices 125 as described herein on a substrate support indicates a percentage increase of about 114% (e.g., from about 700 substrates per mask where the mask was at a floating potential to about 1,500 substrates per mask at ground potential). A substrate support 110 having a plurality of grounding devices 125 as described herein also provides reduced production costs and/or cost of ownership. Testing of the grounding devices 125 as described herein on a substrate support indicates about a 12% decrease in particle generation. Additionally, an improvement in device yield or about 0.6% was realized. Further, testing of the grounding devices 125 as described herein on a substrate support indicated that there was no appreciable change to film properties. Additionally, the plasma density utilizing the grounding devices 125 was not affected.

While the foregoing is directed to embodiments of the disclosure, other and further embodiments of the disclosure may be devised without departing from the basic scope thereof, and the scope thereof is determined by the claims that follow.

1. A substrate support, comprising:
a substrate receiving surface; and
a plurality of compressible grounding devices disposed within a respective opening formed in the substrate support that are located about a periphery of the substrate receiving surface, wherein each of the plurality of grounding devices comprises:
a base member fixed to the substrate support, and
a biasing assembly movably disposed in the base member.

2. The substrate support of claim 1, wherein the biasing assembly comprises a top cover.

3. The substrate support of claim 2, wherein the top cover comprises aluminum.

4. The substrate support of claim 1, wherein the biasing assembly comprises a pin.

5. The substrate support of claim 4, wherein the pin comprises aluminum.

6. The substrate support of claim 4, wherein the pin includes a sloped surface.

7. The substrate support of claim 6, wherein the biasing assembly comprises a top cover.

8. The substrate support of claim 7, wherein sloped surface of the pin is substantially the same as a slope of an internal surface of the top cover.

9. The substrate support of claim 1, wherein the biasing assembly comprises one or both of a top cover and a pin.

10. The substrate support of claim 9, wherein the pin is movable relative to the top cover and the base member.

11. The substrate support of claim 9, wherein top cover and the pin are biased against the base member by a plurality of springs.

12. A substrate support, comprising:
a substrate receiving surface; and
a plurality of compressible grounding devices disposed within a respective opening positioned on a recessed surface of the substrate support along a periphery of the substrate receiving surface, wherein each of the plurality of grounding devices comprises:
a base member fixed to the substrate support, and
a biasing assembly movably disposed in the base member.

13. The substrate support of claim 12, wherein each base member is at least partially embedded in each opening.

14. The substrate support of claim 12, wherein the biasing assembly comprises one or both of a top cover and a pin.

15. The substrate support of claim 14, wherein the pin is movable relative to the top cover and the base member.

16. The substrate support of claim 14, wherein the top cover and the pin are biased against the base member by a plurality of springs.

17. A substrate support, comprising:
a substrate receiving surface; and
a plurality of compressible grounding devices disposed about a periphery of the substrate receiving surface, wherein each of the plurality of grounding devices comprises:
a base member fixed to the substrate support about an opening in a surface of the substrate support;
a pin movably disposed in the base member;
a top cover disposed about the pin;
a plurality of biasing members disposed between the top cover and the base member; and
one or more conductive wires coupled between the pin and the substrate support.

18. The substrate support of claim 17, wherein the pin includes a sloped surface.

19. The substrate support of claim 18, wherein the sloped surface of the pin is substantially the same as a slope of an internal surface of the top cover.

20. The substrate support of claim 17, wherein the base member is at least partially embedded in a recessed surface of the substrate support.
